(19) United States
(12) Patent Application Publication
(10) Pub. No.: US 2024/0217118 A1
(43) Pub. Date: Jul. 4, 2024

(54) GRIPPER MODULE INCLUDING VIBRATION ABSORBER AND SUBSTRATE TRANSPORT APPARATUS INCLUDING A GRIPPER MODULE

(71) Applicant: SEMES CO., LTD., Cheonan-si (KR)

(72) Inventors: Jaehyun LEE, Suwon-si (KR); Hyukjae SUNG, Cheonan-si (KR); Kitae NOH, Seongnam-si (KR); Jonghyun KIM, Asan-si (KR)

(73) Assignee: SEMES CO., LTD., Cheonan-si (KR)

(21) Appl. No.: 18/397,123

(22) Filed: Dec. 27, 2023

(30) Foreign Application Priority Data
Dec. 28, 2022 (KR) 10-2022-0187539

(51) Int. Cl. B25J 15/00; B25J 11/00; B25J 19/00

(52) U.S. Cl. CPC B25J 15/0061; B25J 11/0095; B25J 15/0095; B25J 19/0091

(57) ABSTRACT

The gripper module includes a base plate having a length in a first direction and a width in a second direction that is substantially perpendicular to the first direction; a driver disposed on a base plate to generate a driving power; a gripper transporter disposed on the base plate so as to be connected to the driver, and coupled to the driver and a gripper configured to grip a transport target carrier to linearly transport the gripper between a gripping position and a release position in the first direction; and a vibration absorber connected to the gripper transporter to block an external shock or an external vibration from being transmitted to the gripper.

### CROSS-REFERENCE TO RELATED APPLICATION

This application claims priority to Korean Patent Application No. 10-2022-0187539 filed on Dec. 28, 2022 in the Korean Intellectual Property Office (KIPO), the contents of which are herein incorporated by reference in its entirety.

### BACKGROUND

### 1. Field

Example embodiments of the invention relate to a gripper module configured to grip a carrier, and a substrate transport apparatus including the gripper module. More particularly, example embodiments of the invention relate to a gripper module configured to selectively grip a carrier in which wafers for manufacturing semiconductors are stacked, and a substrate transport apparatus including the gripper module.

### 2. Description of the Related Art

Semiconductor elements may be manufactured by repeatedly performing a process of forming various types of films on a wafer, which is a target substrate, and selectively removing the films. In general, semiconductor process facilities for manufacturing the semiconductor elements may be consecutively arranged to perform various processes on semiconductor substrates.

Targets subjected to a semiconductor element manufacturing process, for example, semiconductor wafers may be provided to each of the semiconductor process facilities or recovered from each of the semiconductor process facilities while being stored in a carrier.

In general, the carrier may be transported by a substrate transport apparatus such as an overhead hoist transport (OHT). The substrate transport apparatus may grip the carrier, and move along a traveling rail that extends along a semiconductor manufacturing line in which the semiconductor process facilities are consecutively arranged so as to transport the carrier to a semiconductor facility corresponding to the carrier.

In this case, various vibrations and shocks may be generated during ascending and descending operations of the substrate transport apparatus due to driving characteristics of the substrate transport apparatus. In particular, when the substrate transport apparatus moves along the traveling rail while gripping the carrier by a gripper module, various traveling vibrations may be generated by rolling contact between a traveling wheel and the rail so as to be transmitted to the carrier. In addition, various shocks or vibrations caused by interaction between components of the gripper module may also be generated during a driving process of the gripper module or the gripping and releasing of a gripper.

The vibrations or the shocks transmitted to the substrate transport apparatus or the gripper module may be transmitted to the carrier gripped by the gripper so as to cause damage or particles to the wafer stored in the carrier, resulting in a transport failure.

In particular, when the traveling vibrations resonate with the gripper module, an accident in which the carrier gripped by the gripper module is separated and dropped from the substrate transport apparatus during traveling may occur.

Accordingly, there is an increasing demand for a novel gripper module capable of absorbing a vibration transmitted to the gripper module configured to grip a carrier to increase a vibration absorption characteristic of the gripper module, and a substrate transport apparatus including the novel gripper module.

### SUMMARY

The present disclosure has been proposed to improve the problems described above, and one object of the present disclosure is to provide a gripper module in which a vibration absorber is disposed in a gripper transporter, so that a vibration may be blocked from being transmitted to a gripper configured to grip a carrier.

Another object of the present disclosure is to provide a substrate transport apparatus including the gripper module described above.

To achieve one object of the present disclosure, according to an exemplary embodiment, a gripper module includes: a base plate having a rectangular shape, and having a length in a first direction and a width in a second direction that is substantially perpendicular to the first direction; a driver disposed on the base plate to generate a driving power; a gripper transporter disposed on the base plate so as to be connected to the driver, and coupled to the driver and a gripper configured to grip a transport target carrier to linearly transport the gripper between a gripping position and a release position in the first direction; and a vibration absorber connected to the gripper transporter to block an external shock or an external vibration from being transmitted to the gripper.

To achieve another object of the present disclosure, according to an exemplary embodiment, a substrate transport apparatus includes: a transport vehicle configured to grip and transport a carrier in which a plurality of substrates are received; a traveling module disposed on an upper portion of the transport vehicle to transport the transport vehicle along a traveling rail connected to a plurality of process facilities; and a gripper module disposed in an inner portion of the transport vehicle to grip the carrier and fix the carrier to the inner portion of the transport vehicle, and configured to block a vibration and a shock to the carrier,

In this case, the gripper module may include: a base plate having a rectangular shape, disposed at an inner top of the transport vehicle, and having a length in a first direction and a width in a second direction that is substantially perpendicular to the first direction; a driver disposed on the base plate to generate a driving power; a gripper transporter disposed on the base plate so as to be connected to the driver, and coupled to the driver and a gripper configured to grip the carrier, which is a transport target, to linearly transport the gripper in the first direction; and a vibration absorber connected to the gripper transporter to block the vibration and the shock from being transmitted to the gripper.

According to a gripper module and a substrate transport apparatus including the same of exemplary embodiments of the present disclosure, the gripper module may be disposed on an upper portion of a transport vehicle to selectively grip and release a carrier according to a substrate transport algorithm. Even when various external shocks or vibrations generated during substrate transport performed by the substrate transport apparatus are applied to the gripper module, the shocks or the vibrations can be effectively absorbed by a vibration absorber and an auxiliary vibration absorber coupled to a transport block. Accordingly, the shocks or the vibrations may be blocked from being applied to the carrier gripped by the gripper, so that damage or particles to a substrate received in the carrier can be prevented. Accordingly, operation stability of the substrate transport apparatus can be improved.

However, effects of the present disclosure are not limited to the above-described effects, and may be variously expanded without departing from the idea and scope of the present disclosure.

### BRIEF DESCRIPTION OF THE DRAWINGS

FIG. 1 is a perspective view showing a substrate transport apparatus according to one embodiment of the present disclosure.

FIG. 2 is a sectional view showing the substrate transport apparatus of FIG. 1 taken in an I-I′ direction.

FIG. 3 is a perspective view showing a gripper module provided in the substrate transport apparatus shown in FIG. 1.

FIG. 4 is a sectional view showing the gripper module of FIG. 3 taken along a transport block.

FIG. 5 is a sectional view showing a coupling structure between the transport block and a vibration absorber shown in FIG. 4 in detail.

### DETAILED DESCRIPTION OF THE EMBODIMENTS

Since various modifications can be made to the present disclosure, and the present disclosure may have various forms, embodiments will be described in detail through the detailed description. This, however, is by no means to restrict the present disclosure to a specific disclosed form, and the present disclosure shall be construed as encompassing all modifications, equivalents, and substitutes included in the idea and technical scope of the present disclosure.

While describing each drawing, similar reference numerals will be used for similar elements. Terms such as “first” and “second” may be used to describe various elements, but the elements are not limited by the terms, and the terms may be used only to distinguish one element from another element.

Terms used herein are intended to describe certain embodiments only, and shall by no means restrict the present disclosure. Unless the context explicitly indicates otherwise, expressions in a singular form include a meaning of a plural form. In the present disclosure, a term such as “comprising” or “including” is intended to designate the presence of characteristics, numbers, steps, operations, elements, parts, or combinations thereof described in the present disclosure, and shall not be construed to preclude any possibility of presence or addition of one or more other characteristics, numbers, steps, operations, elements, parts, or combinations thereof.

Unless otherwise defined, all terms, including technical or scientific terms, used herein have the same meaning as how they are generally understood by a person having ordinary skill in the art to which the present disclosure pertains. Any term as defined in a general dictionary shall be interpreted as having the same meaning as in the context of the relevant art, and shall not be interpreted as having an idealistic or excessively formalistic meaning unless explicitly defined otherwise in the present disclosure.

Hereinafter, exemplary embodiments of the present disclosure will be described in more detail with reference to the accompanying drawings. The same reference numerals will be used for the same elements in the drawings, and redundant descriptions of the same elements will be omitted.

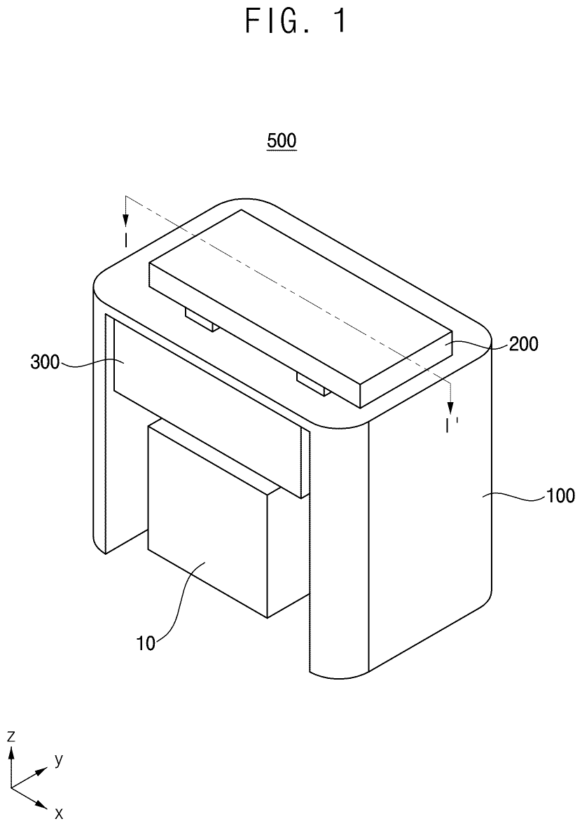

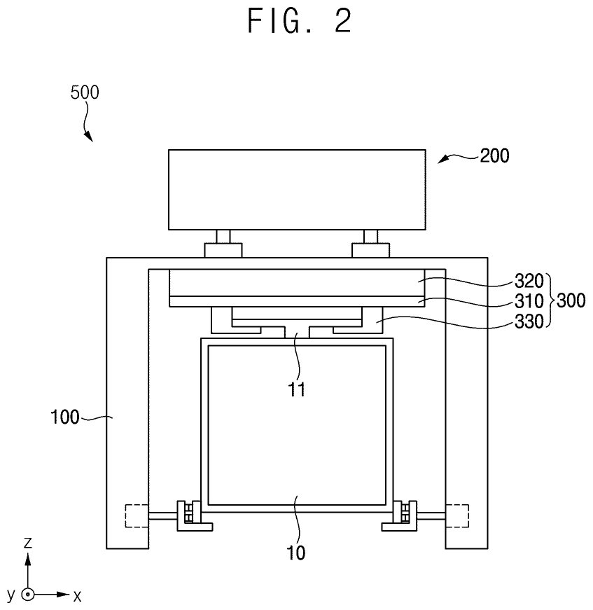

FIG. 1 is a perspective view showing a substrate transport apparatus according to one embodiment of the present disclosure, and FIG. 2 is a sectional view showing the substrate transport apparatus of FIG. 1 taken in an I-I′ direction.

Referring to FIGS. 1 and 2, according to one embodiment of the present disclosure, a substrate transport apparatus 500 may include: a transport vehicle 100 configured to grip and transport a carrier 10 in which a plurality of substrates are received; a traveling module 200 disposed on an upper portion of the transport vehicle 100 to transport the transport vehicle 100 along a traveling rail connected to a plurality of process facilities; and a gripper module 300 disposed in an inner portion of the transport vehicle 100 to grip the carrier 10 and fix the carrier 10 to the inner portion of the transport vehicle 100.

According to one embodiment, the substrate transport apparatus 500 may be used to transport the carrier 10 configured to receive the substrate in a semiconductor element manufacturing process. For example, the substrate transport apparatus 500 may be used to transport a container such as a front-opening unified pod (FOUP) in which semiconductor wafers are stored.

In particular, the substrate transport apparatus 500 may include an overhead hoist transport (OHT) device configured to provide an appropriate substrate to a process facility corresponding to the substrate according to an order of a semiconductor manufacturing process while moving along the traveling rail installed on a ceiling region of a clean room.

The substrate transport apparatus 500 may include the transport vehicle 100 configured to receive the carrier 10, and the traveling module 200 configured to allow the transport vehicle 100 to travel along the traveling rail.

The transport vehicle 100 may include a housing having a side wall configured to separate inner and outer portions of the housing from each other, and an inner space capable of receiving the carrier 10 in the inner portion of the housing. Hereinafter, a longitudinal direction of the housing forming an outward form of the transport vehicle 100 will be defined as a first direction x, a width direction of the housing will be defined as a second direction y, and a height direction of the housing will be defined as a third direction z. The housing may have a hollow inside to receive the carrier 10, and a bottom surface and at least a portion of a side surface of the housing in the second direction y may be opened.

The carrier 10 may be gripped by the gripper module 300 to ascend to the inner portion of the transport vehicle 100 through the bottom surface, or descend downward from the inner portion of the transport vehicle 100 through the bottom surface.

The traveling module 200 may be coupled to the upper portion of the transport vehicle 100 so as to be coupled to the traveling rail connected to the process facilities (not shown). The traveling module 200 may be coupled to an appropriate transport vehicle 100 from a vehicle source provided in a portion of a semiconductor manufacturing fabrication facility in which semiconductor process facilities are aligned so as to be configured as a substrate transport apparatus.

The traveling module 200 may move the transport vehicle 100 to a load port of the process facility in which the carrier 10, which is a transport target, is located according to traveling information set according to a process control algorithm. Thereafter, the gripper module 300 may grip the carrier 10 according to input gripping information to ascend the carrier 10 to the inner portion of the transport vehicle 100.

When the carrier 10 is received in the inner portion of the transport vehicle 100, the traveling module 200 may transport the transport vehicle 100 to an upper portion of a load port of a target process facility. Thereafter, the carrier 10 may descend to the load port of the target process facility, and a gripping state between the carrier and the gripper module may be released.

Therefore, the traveling module 200 may be coupled to the transport vehicle 100, and include: an appropriate process control recognition module configured to transport a processing target substrate between the process facilities according to the control algorithm of the semiconductor manufacturing fabrication facility; and a traveling control module capable of traveling along the traveling rail to move to the target process facility.

According to one embodiment, the gripper module 300 may be disposed at an inner top of the transport vehicle 100 and provided for each transport vehicle 100 to perform a gripping operation on the carrier 10 to transport the carrier.

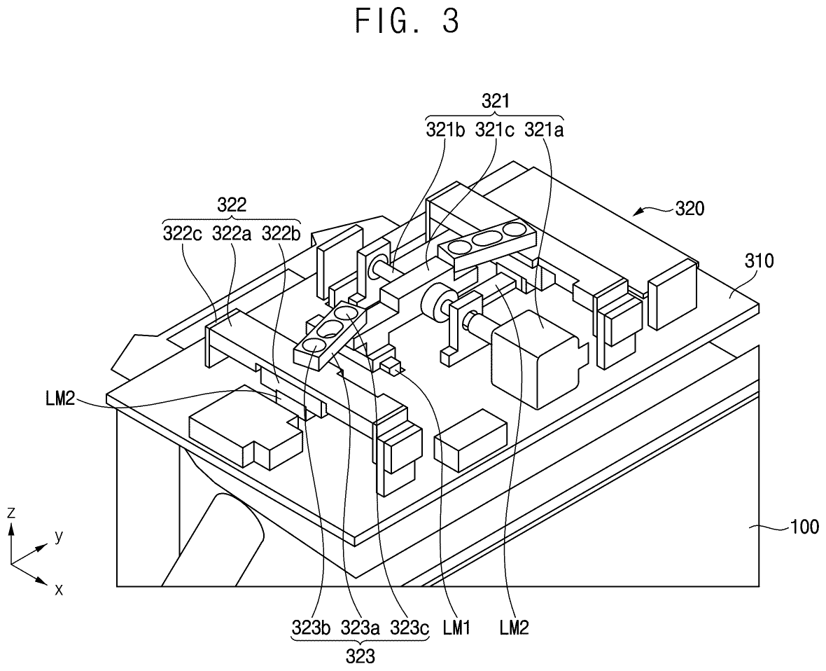

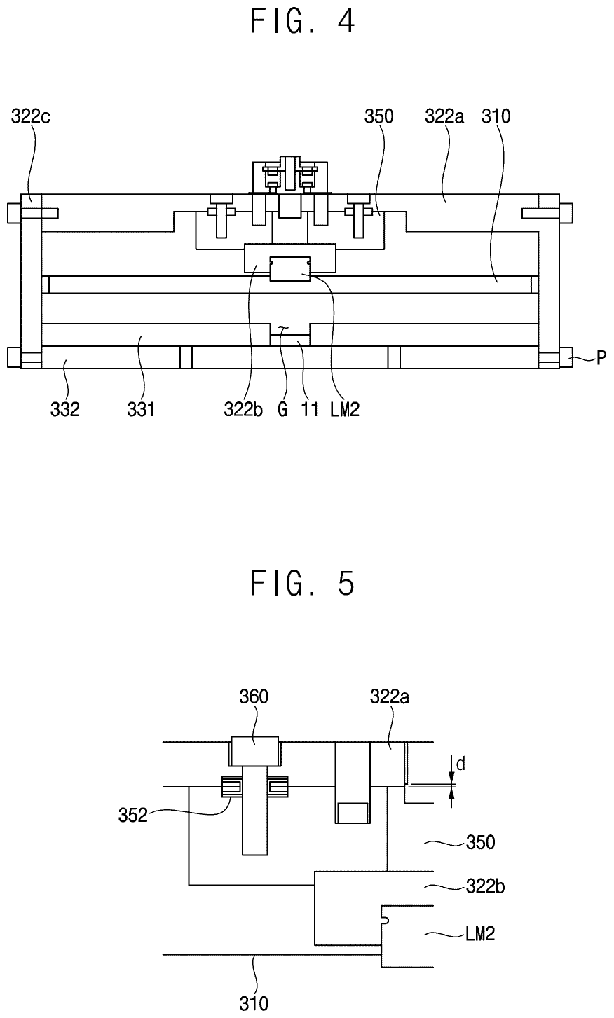

FIG. 3 is a perspective view showing a gripper module provided in the substrate transport apparatus shown in FIG. 1, and FIG. 4 is a sectional view showing the gripper module of FIG. 3 taken along a transport block. FIG. 5 is a sectional view showing a coupling structure between the transport block and a vibration absorber shown in FIG. 4 in detail.

Referring to FIGS. 3 to 5, the gripper module 300 may include: a gripper 330 disposed under the base plate 310 and capable of gripping a flange 11 of the carrier 10; and a gripper controller 320 disposed on the base plate 310 and capable of driving the gripper 330. In particular, a vibration absorber 350 configured to block an external shock or an external vibration from being transmitted to the gripper 330 may be provided in the gripper controller 320.

The base plate 310 may be provided as a reference surface for installing various upper components configured to grip and drive the carrier as well as the gripper controller 320, and the gripper 330 connected to the gripper controller 320 and disposed under the gripper controller 320.

In this case, the base plate 310 may have a base length in the first direction x, and a base width in the second direction y. The base length and the base width may be set to be less than the length and the width of the transport vehicle 100, respectively.

For example, various operation and control components such as a lift and a lift driver configured to allow the gripper 330 to descend and ascend together with the gripper controller 320, and a control module configured to control an overall operation of the gripper module 300 may be arranged as the upper components.

In addition, while the substrate transport apparatus 500 is transporting the carrier, the carrier 10 may be gripped by the gripper 330. Accordingly, the base plate 310 may be configured such that a sum of loads of various upper components including the gripper controller 320, the gripper 330, and the carrier 10 is applied to the base plate 310 as a distributed load. Therefore, the base plate 310 may be provided as a plate having sufficient strength and sufficient rigidity so as to be deformed within an allowable range set for the distributed load.

The gripper controller 320 may include a driver 321, a gripper transporter 322, and a link block 323.

The driver 321 may include: a power source 321a configured to generate a driving power; a ball screw 321b configured to linearly move in the second direction y according to the driving power; and a driving block 321c having a central portion fixed to the ball screw 321b to linearly move in the second direction y together with the ball screw 321b.

The power source 321a may be configured as a servo motor configured to drive the ball screw 321b, and the ball screw 321b may be connected to the power source 321a by a bearing and a coupler. Accordingly, a rotational movement of the motor generated by the servo motor may be converted into a linear movement in the second direction y through the ball screw 321b.

The driving block 321c may be fixed to the ball screw 321b to move in the second direction y together with the ball screw 321b. In this case, the driving block 321c may have the central portion fixed to the ball screw 321b, and may be provided in a line shape extending in the first direction x.

According to the present embodiment, the driving block 321c may have both ends located symmetrically with respect to the ball screw 321b. Accordingly, a pair of link blocks 323, which will be described below, may be coupled to the both ends of the driving block 321c while being spaced apart from the ball screw 321b by the same distance.

In this case, one end of the driving block 321c may be coupled to a driving rail LM1 disposed under the one end of the driving block 321c to minimize a rolling resistance against the linear movement of the driving block 321c in the second direction. The remaining end except for the end that makes contact with the driving rail LM1 may be spaced apart from the base plate 310 without making contact with the rail. Therefore, the driving block 321c may linearly move along the driving rail LM1 disposed on only one side of the driving block 321c to minimize a movement resistance during a process of the linear movement.

Accordingly, a rotational driving force of the power source 321a may be converted into a linear driving force by the driving block 321c and transmitted to the gripper transporter 322 through the link block 323.

The gripper transporter 322 may include: a transport block 322a spaced apart from an end of the driving block 321c in the first direction x, extending in the second direction y in a line shape, and configured to linearly move in the first direction x; a transport bracket 322b coupled to a lower portion of the transport block 322a to transport the transport block 322a in the first direction x; and a gripper coupling plate 322c coupled to both ends of the transport block 322a, and extending in a third direction z that is perpendicular to the first direction x and the second direction y to penetrate through the base plate 310 so as to be coupled to the gripper 330 located under the base plate 310.

The transport block 322a may be connected to the gripper 330 disposed under the base plate 310 to function as a support body configured to support the gripper 330. Accordingly, the transport block 322a may be provided as a plate having sufficient strength and sufficient rigidity to support a load of the gripper 330, and having a sufficient length to receive a width of the carrier 10 gripped by the gripper 330.

Therefore, while the driving block 321c has the line shape extending in the first direction x, the transport block 322a may be provided as a line-shaped plate extending in the second direction y while being spaced apart from the both ends of the driving block 321c. Accordingly, transport blocks 322a may be provided as a pair of line plates arranged symmetrically with respect to the driving block 321c.

In this case, the pair of transport blocks 322a may be spaced apart from the base plate 310 by a predetermined distance in order to reduce a movement resistance during a transport operation. In other words, the transport bracket 322b may be disposed at a central lower portion of the transport block 322a, and the transport bracket 322b may be coupled onto a transport rail LM2 disposed on the base plate 310 to linearly move in the first direction by the driving force transmitted from the driving block 321c.

Accordingly, the transport rail LM2 may be disposed on the base plate 310, the transport bracket 322b may be coupled on to the transport rail LM2, and the transport block 322a may be coupled to the transport bracket 322b. Accordingly, the transport block 322a may move in the first direction x together with the transport bracket 322b while being spaced apart from the base plate 310 by a predetermined distance.

In particular, the vibration absorber 350 may be disposed between the transport block 322a and the transport bracket 322b to absorb the vibration or the shock applied to the transport block 322a so as to block the vibration or the shock from being transmitted to the gripper 330 disposed on a lower side.

For example, the vibration absorber 350 may include a vibration absorption pad fixed by a fixing bolt 360 to cover a central rear surface of the transport block 322a, and having a width that is greater than a width of the transport bracket 322b in the second direction y.

The vibration absorption pad may cover the central rear surface of the transport block 322a to which the gripper 330 is connected to absorb the shock or the vibration applied to the gripper module 300. Accordingly, the shock or the vibration generated by the transport vehicle 100 or the traveling module 200 may be suppressed from being applied to the gripper 330.

Since the transport block 322a is a starting point of connection with the gripper 330 in the substrate transport apparatus 500, the vibration absorption pad may be installed in the transport block 322a to block the external vibration or the external shock from being transmitted to the gripper 330, and to function as a vibration absorption structure for the gripper 330.

For example, the vibration absorption pad may be formed of one of rubber, silicone, polyurethane, and a composite thereof. However, since the above configuration has been provided for illustrative purposes, the vibration absorption pad may be formed of various materials that have excellent vibration absorption characteristics and may be stably coupled to the transport block 322a.

In this case, the vibration absorber 350 may be arranged to have a gap d within a predetermined range with respect to the transport block 322a. When the gap d is too large, the vibration absorber 350 may be spaced apart from the transport block 322a so as to be arranged as a separate member. Accordingly, it may become difficult for the vibration absorber 350 to implement a vibration absorption characteristic.

Conversely, when the vibration absorber 350 and the transport block 322a excessively make close contact with each other, the vibration absorber 350 may be compressed to have increased hardness and reduce a function of absorbing a vibration. Accordingly, the gap d between the vibration absorber 350 and the transport block 322a may be set to a range of about 0.1 mm to 0.5 mm.

However, the gap d may be variously set to implement a sufficient vibration absorption characteristic. In particular, an optimal vibration absorption characteristic may be set to vary depending on physical properties and shape characteristics of the vibration absorber 350 and the transport block 322a. An optimal gap d may be set in consideration of the physical properties of the vibration absorber 350 and the transport block 322a.

In some embodiments, an auxiliary vibration absorber 352 disposed between the transport block 322a and the vibration absorber 350 at a peripheral portion of the fixing bolt 360 may be further included.

Since the fixing bolt 360 is provided in a shape of a rod that penetrates through the transport block 322a, when the external shock or the external vibration is applied to the gripper module 300, the shock or the vibration may be concentrated on the fixing bolt 360.

Accordingly, the auxiliary vibration absorber 352 may preemptively absorb the shock or the vibration concentrated on the peripheral portion of the fixing bolt 360 to weaken the shock or the vibration applied to the vibration absorber 350. Accordingly, the shock or the vibration applied to the gripper module 300 may be absorbed twice by the vibration absorber 350 and the auxiliary vibration absorber 352, so that the vibration absorption characteristic of the substrate transport apparatus 500 may be improved.

For example, the auxiliary vibration absorber 352 may be configured as a rubber packing surrounding the fixing bolt 360. However, it is obvious that the auxiliary vibration absorber 352 may be formed of various materials capable of sufficiently absorbing relatively large vibrations or shocks.

The driving power may be transmitted to the gripper transporter 322 by the link block 323. The link block 323 may be rotatably coupled to the driving block 321c and the transport block 322a to convert the linear movement of the driving block 321c in the second direction y into the linear movement of the transport block 322a in the first direction x.

For example, the link block 323 may include: a body 323a having a bar shape; a first rotational coupler 323b penetrating through a first end of the body 323a to fix the body 323a to the transport block 322a; and a second rotational coupler 323c penetrating through a second end of the body 323a to fix the body 323a to the driving block 321c.

The body 323a may be provided as a bar-shaped plate having sufficient strength to transmit the linear movement of the driving block 321c to the transport block 322a. Since the body 323a rotates at an end of the driving block 321c and a central portion of the transport block 322a, the body 323a may be formed of various materials having various shapes, which have sufficient rigid body characteristics to perform the rotational movement.

The first and second rotational couplers 323b and 323c may be configured as various structures capable of fixing the transport block 322a and the driving block 321c while rotating the body 323a in order to convert the linear movement of the driving block 321c in the second direction y into the linear movement of the transport block 322a in the first direction.

For example, the first and second rotational couplers 323b and 323c may be configured as one of a bearing structure, a pin structure, and a lubricated friction structure disposed inside a through-hole formed through the first and second ends of the body 323a.

When the driving block 321c linearly moves in a direction away from the power source 321a in the second direction y, the body 323a of the link block 323 coupled to the driving block 321c by the second rotational coupler 323c may move in the direction away from the power source 321a by the driving block 321c while rotating.

In this case, since the transport block 322a is coupled to the link block 323 by the first rotational coupler 323b, similar to the second rotational coupler 323c, the transport block 322a may move in a direction toward the ball screw 321b while rotating.

Accordingly, the transport block 322a may be transported in the direction toward the ball screw 321b in the first direction x. In this case, since the transport blocks 322a are located symmetrically with respect to the ball screw 321b, the pair of transport blocks 322a may move closer to each other toward the ball screw 321b.

Conversely, when the driving block 321c moves toward the power source 321a, the pair of transport blocks 322a may move in the first direction x so as to move away from each other from the ball screw 321b through the same process.

According to one embodiment, the gripper 330 may penetrate through the base plate 310 so as to be coupled to the transport block 322a, and may move between a gripping position P1 and a release position P2 according to the linear movement of the transport block 322a. The carrier may be gripped at the gripping position P1, and the gripper 330 performing the gripping may be separated from the carrier 10 at the release position P2.

For example, the gripper 330 may include: a pair of upper blocks 331 coupled to ends of a pair of gripper coupling plates 322c extending under the base plate 310, respectively, and extending in the second direction y to face each other while being spaced apart from each other by a reception space configured to receive the carrier 10; and a lower block 332 having a line shape extending in the second direction y, and coupled to a rear surface of the upper block 331 to cover the reception space RS so as to provide the reception space RS as a reception groove G configured to receive a flange of the carrier 10.

The gripper coupling plate 322c may be coupled to the both ends of the transport block 322a, and may extend downward to penetrate through a through-line provided on the base plate 310. The through-line may extend in the first direction x, and may have a length that is longer than a width of the gripper coupling plate 322c.

Therefore, the gripper coupling plate 322c may be coupled to the both ends of the transport block 322a by a fixing device P to penetrate through the through-line, so that the gripper coupling plate 322c may move in the same direction as the transport block 322a while penetrating through the through-line when the transport block 322a is moved by the driving power transmitted by the driving block 321c and the link block 323.

Since the gripper 330 is fixed to the gripper coupling plate 322c by the fixing device P, the gripper 330 may also be moved by the movement of the gripper coupling plate 322c. Therefore, when the driving block 321c moves away from the power source 321a, the pair of transport blocks 322a may move closer to each other in the first direction x, so that the pair of gripper coupling plates 322c coupled to the pair of transport blocks 322a, respectively, may move to a position adjacent to the driver 321.

In this case, grippers 330 fixed to the pair of gripper coupling plates 322c, respectively, may be arranged closest to each other in the first direction so as to be arranged at the gripping position at which the carrier 10 is gripped.

Conversely, when the driving block 321c moves closer to the power source 321a, the pair of transport blocks 322a may move away from each other in the first direction x, so that the pair of gripper coupling plates 322c coupled to the pair of transport blocks 322a, respectively, may be spaced apart from the driver 321. In this case, the grippers 330 fixed to the pair of gripper coupling plates 322c, respectively, may be arranged farthest from each other in the first direction x so as to be arranged at the release position.

The pair of grippers 330 may be closest to each other at the gripping position, and each flange 11 disposed on an upper portion of the carrier 10 as shown in FIG. 2 may be received in the reception groove G provided in each of the grippers 330. Accordingly, the carrier 10 may be gripped by the pair of grippers 330.

When the carrier 10 is gripped by the gripper 330, the gripper coupling plate 322c may ascend to receive the carrier 10 at the inner top of the transport vehicle 100. When the carrier 10 is received in the inner portion of the transport vehicle 100, the traveling module 200 may move the transport vehicle 100 toward the target process facility. When the carrier 10 is located at the load port of the target process facility, the gripper 330 may move to the release position so as to be separated from the carrier 10. Accordingly, substrate transport from a source process facility to the target process facility may be completed.

While the substrate transport is being performed, the external shock or the external vibration applied to the gripper module 300 may be absorbed by the vibration absorber 350 and the auxiliary vibration absorber 352 so as to be blocked from being transmitted to the gripper 330. Accordingly, the substrate inside the carrier 10 may be prevented from being damaged by the external shock or the external vibration.

According to the gripper module and the substrate transport apparatus including the same of one embodiments of the present disclosure, the gripper module may be disposed on the upper portion of the transport vehicle 100 to selectively grip and release the carrier according to a substrate transport algorithm. Even when various external shocks or vibrations generated during the substrate transport performed by the substrate transport apparatus are applied to the gripper module 300, the shocks or the vibrations may be effectively absorbed by the vibration absorber 350 and the auxiliary vibration absorber 352 coupled to the transport block 322a. Accordingly, the shocks or the vibrations may be blocked from being applied to the carrier 10 gripped by the gripper 330, so that damage or particles to the substrate received in the carrier may be prevented. Accordingly, operation stability of the substrate transport apparatus 500 may be improved.

Although exemplary embodiments of the invention have been described above, it will be understood by a person having ordinary skill in the art that various modifications and changes can be made to the present disclosure without departing from the idea and scope of the invention as set forth in the appended claims.

1. A gripper module comprising:
a base plate having a rectangular shape, and having a length in a first direction and a width in a second direction that is substantially perpendicular to the first direction;
a driver disposed on the base plate to generate a driving power;
a gripper transporter disposed on the base plate so as to be connected to the driver, and coupled to the driver and a gripper configured to grip a transport target carrier to linearly transport the gripper between a gripping position and a release position in the first direction; and
a vibration absorber connected to the gripper transporter to block an external shock or an external vibration from being transmitted to the gripper.

2. The gripper module of claim 1, wherein the driver includes a driving block extending in the first direction, and configured to linearly move in the second direction according to the driving power, and
the gripper transporter includes a transport block spaced apart from an end of the driving block in the first direction, extending in the second direction, and configured to linearly move in the first direction according to the linear movement of the driving block.

3. The gripper module of claim 2, wherein the gripper transporter includes:
a transport bracket coupled to a lower portion of the transport block to linearly transport the transport block in the first direction;
a transport rail to which the transport bracket is coupled, and located on the base plate to extend in the first direction; and
a gripper coupling plate coupled to both ends of the transport block, and extending in a third direction that is substantially perpendicular to the first direction and the second direction to penetrate through the base plate so as to be coupled to the gripper located under the base plate, and
wherein the vibration absorber is disposed between the transport block and the transport bracket to absorb the shock or the vibration applied to the transport block.

4. The gripper module of claim 3, wherein the vibration absorber includes a vibration absorption pad fixed by a fixing bolt to cover a central rear surface of the transport block, and having a width that is greater than a width of the transport bracket in the second direction.

5. The gripper module of claim 4, wherein the vibration absorption pad includes one of rubber, silicone, polyurethane, and a composite thereof.

6. The gripper module of claim 4, further comprising an auxiliary vibration absorber disposed between the transport block and the vibration absorber at a peripheral portion of the fixing bolt.

7. The gripper module of claim 6, wherein the auxiliary vibration absorber includes a rubber packing surrounding the fixing bolt.

8. The gripper module of claim 3, further comprising a link block rotatably coupled to the driving block and the transport block to convert the linear movement of the driving block in the second direction into the linear movement of the transport block in the first direction.

9. The gripper module of claim 8, wherein the link block includes:
a body having a bar shape; and
first and second rotational couplers penetrating through both ends of the body to rotatably couple the body to the transport block and the driving block, respectively.

10. The gripper module of claim 9, wherein each of the first and second rotational couples includes one of a bearing structure, a pin structure, and a lubricated friction structure.

11. The gripper module of claim 9, wherein a pair of transport blocks are disposed on the base plate while being spaced apart from both ends of the driving block by a same distance, and individually coupled to the both ends of the single driving block by a pair of link blocks, and
a pair of the vibration absorbers are individually located on central rear surfaces of the pair of transport blocks.

12. The gripper module of claim 11, wherein a pair of grippers are connected to both ends of each of the pair of transport blocks so as to traverse the base plate in the second direction, and configured to linearly move closer to or away from each other between the gripping position and the release position according to the linear movement of the transport block.

13. The gripper module of claim 12, wherein the gripper includes:
a pair of upper blocks coupled to ends of a pair of gripper coupling plates extending under the base plate, respectively, and extending in the second direction to face each other while being spaced apart from each other by a reception space configured to receive the carrier; and
a lower block having a line shape extending in the second direction, and coupled to a rear surface of the upper block to cover the reception space so as to provide the reception space as a reception groove configured to receive a flange of the carrier.

14. A substrate transport apparatus comprising:
a transport vehicle configured to grip and transport a carrier in which a plurality of substrates are received;
a traveling module disposed on an upper portion of the transport vehicle to transport the transport vehicle along a traveling rail connected to a plurality of process facilities; and
a gripper module disposed in an inner portion of the transport vehicle to grip the carrier and fix the carrier to the inner portion of the transport vehicle, and configured to block a vibration and a shock to the carrier,
wherein the gripper module includes:
a base plate having a rectangular shape, disposed at an inner top of the transport vehicle, and having a length in a first direction and a width in a second direction that is substantially perpendicular to the first direction;
a driver disposed on the base plate to generate a driving power;
a gripper transporter disposed on the base plate so as to be connected to the driver, and coupled to the driver and a gripper configured to grip the carrier, which is a transport target, to linearly transport the gripper in the first direction; and
a vibration absorber connected to the gripper transporter to block the vibration and the shock from being transmitted to the gripper.

15. The substrate transport apparatus of claim 14, wherein the driver includes a driving block extending in the first direction, and configured to linearly move in the second direction according to the driving power, and
the gripper transporter includes a transport block spaced apart from an end of the driving block in the first direction, extending in the second direction, and configured to linearly move in the first direction according to the linear movement of the driving block.

16. The substrate transport apparatus of claim 15, wherein the gripper transporter includes:
a transport bracket coupled to a lower portion of the transport block to linearly transport the transport block in the first direction;
a transport rail to which the transport bracket is coupled, and located on the base plate to extend in the first direction; and
a gripper coupling plate coupled to both ends of the transport block, and extending in a third direction that is substantially perpendicular to the first direction and the second direction to penetrate through the base plate so as to be coupled to the gripper located under the base plate, and
wherein the vibration absorber is disposed between the transport block and the transport bracket to absorb the shock or the vibration applied to the transport block.

17. The substrate transport apparatus of claim 16, wherein the vibration absorber includes a vibration absorption pad fixed by a fixing bolt to cover a central rear surface of the transport block, and having a width that is greater than a width of the transport bracket in the second direction.

18. The substrate transport apparatus of claim 17, wherein the vibration absorption pad includes one of rubber, silicone, polyurethane, and a composite thereof.

19. The substrate transport apparatus of claim 17, further comprising an auxiliary vibration absorber disposed between the transport block and the vibration absorber at a peripheral portion of the fixing bolt.

20. The substrate transport apparatus of claim 19, wherein the auxiliary vibration absorber includes a rubber packing surrounding the fixing bolt.
